(19) United States
(12) Patent Application Publication
(10) Pub. No.: US 2024/0113068 A1
(43) Pub. Date: Apr. 4, 2024

(54) ULTRAFINE-PITCH ALL-COPPER INTERCONNECT STRUCTURE AND FORMING METHOD THEREOF

(71) Applicant: Guangdong University of Technology, Guangzhou (CN)

(72) Inventors: Yu ZHANG, Guangzhou (CN); Ranyuan ZHANG, Guangzhou (CN); Junyu HE, Guangzhou (CN); Wenjun HUANG, Guangzhou (CN); Chengqiang CUI, Guangzhou (CN); Guannan YANG, Guangzhou (CN)

(21) Appl. No.: 18/500,714

(22) Filed: Nov. 2, 2023

(30) Foreign Application Priority Data
Nov. 3, 2022 (CN) 202211371335.5

(51) Int. Cl. H01L 23/00

(52) U.S. Cl. CPC H01L 24/81; H01L 2224/81011; H01L 2224/81098; H01L 2224/81205; H01L 2224/8184; H01L 2924/01029

(57) ABSTRACT

A method for forming an ultrafine-pitch all-copper interconnect structure is provided. Nano-copper particles are mixed with a solvent, a dispersant and a viscosity modifier to prepare a nano-copper paste. A chip with a preset number of copper pillars having a preset diameter and a substrate are selected, cleaned and pretreated. The chip is sucked and flipped by a bonding machine to make the copper pillars face outward. The chip is sucked through a suction nozzle of the bonding machine and dipped in the nano-copper paste. A protective gas is fed, and the copper pillars are aligned with copper pads on the substrate through an optical system of the bonding machine, bonded with the substrate at a preset pressure and temperature under ultrasonication, and cooled at room temperature to obtain the interconnect structure. An ultrafine-pitch all-copper interconnect structure fabricated by the method is also provided.

### CROSS-REFERENCE TO RELATED APPLICATIONS

This application claims the benefit of priority from Chinese Patent Application No. 202211371335.5, filed on Nov. 3, 2022. The content of the aforementioned application, including any intervening amendments made thereto, is incorporated herein by reference in its entirety.

### TECHNICAL FIELD

This application relates to ultrafine-pitch all-copper interconnection, and more particularly to an ultrafine-pitch all-copper interconnect structure and a forming method thereof.

### BACKGROUND

The combination of various electronic components in a single package is becoming more and more important in the field of 2.5D and 3D integration. An increase in functional dimension of each electronic component is accompanied by a decrease in structure size, and the corresponding flip-chip interconnection bumps will be reduced from 40-50 μm to 5 μm. Tin has reflow properties, so traditional lead-free solder bumps will collapse during reflow, which makes it impossible to guarantee a height of the bumps when making ultrafine-pitch bumps.

The commonly-used copper-pillar bumps are formed by a copper pillar and a top tin cap, which will still experience collapse during reflow. Because of the relatively low proportion of tin, the collapse within a certain pitch range has little effect on the bump height. However, as the connection pitch becomes smaller and smaller, it is necessary to replace the tin cap with pure copper or silver. Through ultrasonic-assisted sintering of micron silver paste, the ultrafine-pitch micro-copper pillar interconnection has been achieved in the prior art.

However, the traditional solder coating methods have limitations in terms of ultrafine-pitch interconnection, and fail to achieve all-copper interconnection at low temperatures. Moreover, the traditional methods have poor interconnect effect, thereby failing to meet requirements of high-density packaging.

### SUMMARY

An object of the disclosure is to provide an ultrafine-pitch all-copper interconnect structure and a forming method thereof involving low-temperature sintering, which can achieve the ultimate ultrafine-pitch interconnection and meet requirements of high-density packaging, so as to overcome the technical defects existing in the prior art.

In a first aspect, this application provides a method for forming an ultrafine-pitch all-copper interconnect structure, comprising:
step (1) mixing nano-copper particles with a solvent, a dispersant and a viscosity modifier to prepare a nano-copper paste;
step (2) selecting and cleaning a chip with a preset number of copper pillars having a preset diameter and a substrate followed by pretreatment;
step (3) loading the substrate into a bonding machine, sucking, by the bonding machine, the chip and flipping the chip, such that the copper pillars face outward;
step (4) sucking the chip by a suction nozzle of the bonding machine to dip the copper pillars in the nano-copper paste;
step (5) feeding a protective gas, aligning the copper pillars respectively with copper pads on the substrate through an optical system of the bonding machine and performing bonding at a preset pressure and a preset temperature under ultrasonication; and
step (6) performing cooling at room temperature to obtain the ultrafine-pitch all-copper interconnect structure.

In some embodiments, the step (1) specifically comprises the following sub-step:
preparing the nano-copper particles, the solvent, the dispersant and the viscosity modifier into the nano-copper paste;
wherein the nano-copper particles have a particle size of 100 nm or less; and a mass percentage concentration of the nano-copper particles in the nano-copper paste is 80% or more.

In some embodiments, in step (1), the solvent is selected from the group consisting of ethylene glycol, terpineol, polyethylene glycol, rosin, acetone, chloroform, cyclohexane, epichlorohydrin, epoxy resin, primary amine, tertiary amine, and a combination thereof;
the dispersant is selected from the group consisting of gum arabic, polyvinyl alcohol, polyethylene glycol, gelatin, polyvinyl imidazolidinone, 1-methylimidazole, 2-methylimidazole, 4-methylimidazole, phenylimidazole, 2-ethylimidazole, and a combination thereof; and
the viscosity modifier is selected from the group consisting of methylcellulose, ethylcellulose, hydroxycellulose, primary amine, tertiary amine, acid anhydride and a combination thereof.

In some embodiments, the step (2) specifically comprises the following sub-steps:
step (21) selecting the chip with 4-500 copper pillars with input/output (I/O) ports each having a diameter of 5-50 μm and a pitch of 10-100 μm and a substrate; and
step (22) cleaning and pretreating the chip and the substrate.

In some embodiments, the pretreatment is acid treatment, plasma treatment, SAM or a combination thereof.

In some embodiments, the method further comprises:
step (23) after step (2), subjecting the chip to nitrogen purging in a vacuum dry box and cold argon plasma treatment at room temperature to remove a protective layer;
wherein a flow rate of the cold argon plasma treatment is 300 sccm.

In some embodiments, the step (4) specifically comprises the following sub-step:
operating the suction nozzle of the bonding machine in a closed environment in the presence of the protective gas to suck the chip, and dipping the copper pillars into the nano-copper paste.

In some embodiments, in step (5), the protective gas is an inert gas or a reducing gas; the inert gas is nitrogen, argon or helium; and the reducing gas is hydrogen, formaldehyde or carbon monoxide.

In some embodiments, in step (5), the bonding is performed at 150-300° C. and 0-50 MPa under an ultrasonic frequency of 0-100 kHz.

In a second aspect, this application provides an ultrafine-pitch all-copper interconnect structure, which is obtained by the above forming method.

Compared to the prior art, the present disclosure has the following beneficial effects.

In this disclosure, an ultrafine-pitch all-copper interconnect structure is obtained by mixing nano-copper particles with a solvent, a dispersant and a viscosity modifier to prepare a nano-copper paste; selecting and cleaning a chip with a preset number of copper pillars having a preset diameter and a substrate followed by pretreatment; loading the substrate into a bonding machine, sucking, by the bonding machine, the chip and flipping the chip, such that the copper pillars face outward; sucking the chip by a suction nozzle of the bonding machine to dip the copper pillars in the nano-copper paste; feeding a protective gas, aligning the copper pillars respectively with copper pads on the substrate through an optical system of the bonding machine and performing bonding at a preset pressure and a preset temperature under ultrasonication; and performing cooling at room temperature. This application involves low-temperature sintering and all-copper interconnection. Moreover, a way of dipping the nano-copper paste effectively breaks through limits of a traditional solder coating method in achieving ultrafine-pitch interconnection, which can achieve the ultimate ultrafine-pitch interconnection and meet requirements of high-density packaging.

### BRIEF DESCRIPTION OF THE DRAWINGS

The present disclosure will be described in detail below with reference to the accompanying drawings. The above and other aspects of the present disclosure will become clearer and easier to understand through the following detailed description in conjunction with the accompanying drawings.

FIG. 1 is a flow chart of a method for forming an ultrafine-pitch all-copper interconnect structure according to an embodiment of the present disclosure;

FIG. 2 is a flow chart of step (2) of the method according to an embodiment of the present disclosure; and

FIG. 3 schematically illustrates the forming method according to an embodiment of the present disclosure.

### DETAILED DESCRIPTION OF EMBODIMENTS

The present disclosure will be further described below with reference to the embodiments and accompanying drawings.

The embodiments disclosed herein are merely illustrative of the disclosure, and are not intended to limit the present disclosure. In addition to the embodiments described herein, any modifications, changes and replacements made by those skilled in the art without departing from the spirit of the disclosure shall fall within the scope of the disclosure defined by the appended claims.

### Embodiment 1

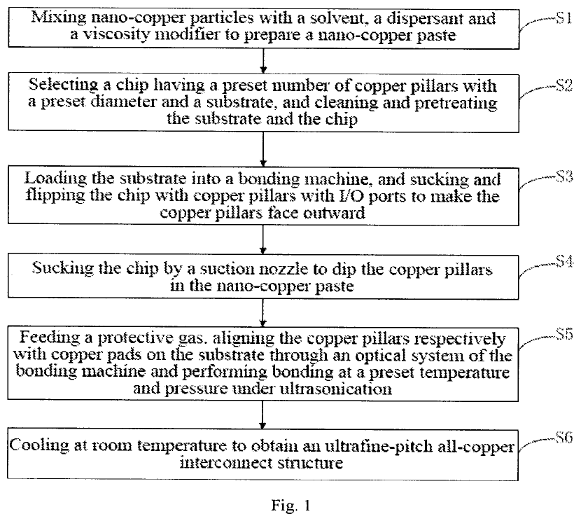

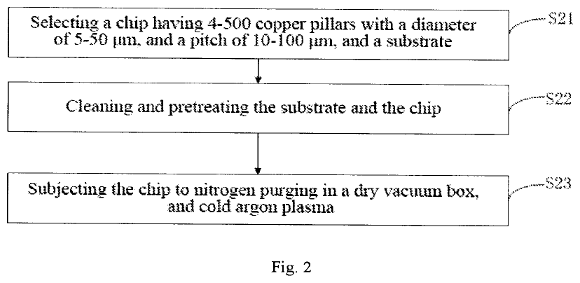

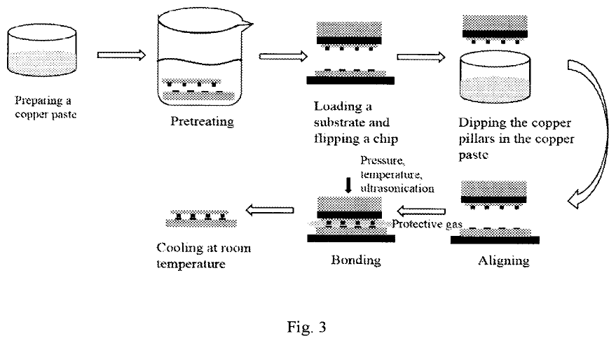

The embodiment illustrated in FIGS. 1-3 provides a method for forming an ultrafine-pitch all-copper interconnect structure, which includes the following steps.
(S1) A nano-copper paste was prepared and adjusted to a certain concentration with a solvent, a dispersant and a viscosity modifier.
(S2) A chip with a preset number of copper pillars having a preset diameter and a substrate were selected, cleaned and then pretreated.
(S3) The substrate was loaded into a bonding machine. The chip with copper pillars with I/O ports was sucked and flipped by the bonding machine to make the copper pillars face outward.
(S4) The chip was sucked through a suction nozzle of the bonding machine so that the copper pillar structures were immersed in the nano-copper paste to dip the nano-copper paste and lifted.
(S5) A protective gas was fed, and the copper pillars were aligned respectively with copper pads on the substrate through an optical system of the bonding machine, bonded with the substrate at a preset pressure and temperature under ultrasonication.
(S6) After cooling at room temperature, an ultrafine-pitch all-copper semiconductor interconnect structure was obtained.

Specifically, through the above steps S1-S6, this application involves low-temperature sintering and all-copper interconnection. Moreover, a way of dipping the nano-copper paste effectively breaks through limits of a traditional solder coating method in achieving ultrafine-pitch interconnection, which can achieve the ultimate ultrafine-pitch interconnection and meet requirements of high-density packaging. This can achieve the pure copper interconnection without a presence of other intermetallic compounds. The way of dipping the nano-copper paste can also achieve finer pitch interconnection than the traditional coating method, and achieve lower temperature interconnection through a low melting point of nano-copper materials.

In this embodiment, S1 specifically included the following sub-step. Nano-copper particles, a solvent, a dispersant and a viscosity modifier were prepared into a nano-copper paste. The nano-copper particles had a particle size of 100 nm or less. A mass percentage concentration of the nano-copper particles in the nano-copper paste was 80% or more.

Specifically, nano-copper particles, a solvent, a dispersant and a viscosity modifier were put into a container and stirred so that the nano-copper particles, the solvent, the dispersant and the viscosity modifier were evenly mixed, thereby preparing a suitable nano-copper paste. The nano-copper particles had a particle size of 100 nm or less. A mass percentage concentration of the nano-copper particles in the nano-copper paste was 80% or more. This resulted in better sintering effect and faster finished product efficiency.

In this embodiment, in S1, the solvent was selected from the group consisting of ethylene glycol, terpineol, polyethylene glycol, rosin, acetone, chloroform, cyclohexane, epichlorohydrin, epoxy resin, primary amine, tertiary amine, and a combination thereof, which results in good solvent effect, good catalytic effect and high reaction efficiency of the nano-copper particles, which resulted in good solvent effect, good catalytic effect and high reaction efficiency of the nano-copper particles.

The dispersant was selected from the group consisting of gum arabic, polyvinyl alcohol, polyethylene glycol, gelatin, polyvinyl imidazolidinone, 1-methylimidazole, 2-methylimidazole, 4-methylimidazole, phenylimidazole, 2-ethylimidazole, and a combination thereof. Surfactants described above with opposite properties of lipophilic and hydrophilic can uniformly disperse solid and liquid particles of inorganic and organic pigments that are difficult to dissolve in liquids, and can also prevent a sedimentation and an agglomeration of particles and form an amphiphilic reagent required for stable suspension, which facilitate a dissolution of the nano-copper particles with good mixing effect.

The viscosity modifier was selected from the group consisting of methylcellulose, ethylcellulose, hydroxycellulose, primary amine, tertiary amine, acid anhydride and a combination thereof. Methylcellulose has excellent wettability, dispersion, adhesion, thickening, emulsification, water retention and film-forming properties, as well as impermeability to grease. Therefore, the viscosity modifier can increase a reaction efficiency of the nano-copper particles, the solvent, and the dispersant.

In this embodiment, S2 specifically included the following sub-steps.
(S21) A chip having 4-500 copper pillars with a diameter of 5-50 μm, and a pitch of 10-100 μm, and a substrate were selected.
(S22) The chip and the substrate were cleaned and then pretreated.

Specifically, through the above steps S21-S22, the copper pillars were appropriately selected and the pitch of the chip was good, which facilitated cleaning and pretreating of the substrate and the chip, making surfaces of the substrate and the chip clean and convenient for processing.

In this embodiment, the pretreatment was acid treatment, plasma treatment, SAM or a combination thereof.

The acid treatment included a dilute sulfuric acid treatment and a dilute hydrochloric acid treatment, which were used to remove metal dust on the surfaces of the substrate and the chip.

The plasma treatment included Ar plasma treatment and N₂ plasma passivation surface.

The SAM treatment was to perform RCA cleaning and then immersing the chip in a propanethiol solution (1 mM).

In this embodiment, after S2, the method further included the following step.
(S23) The chip was subjected to nitrogen purging in a vacuum dry box and cold argon plasma treatment at room temperature to remove a protective layer. A flow rate of the cold argon plasma treatment was 300 sccm.

In this embodiment, S4 specifically included the following step.

The chip was sucked through the suction nozzle of the bonding machine in a closed environment in the presence of the protective gas, and the copper pillars were dipped in the nano-copper paste.

In this embodiment, in S5, the protective gas was an inert gas or a reducing gas, the inert gas was nitrogen, argon or helium, and the reducing gas was hydrogen, formaldehyde or carbon monoxide. This resulted in good protection effect and good safety during processing.

In this embodiment, in S5, the bonding was performed at 150-300° C. and 0-50 MPa under an ultrasonic frequency of 0-100 kHz.

### Embodiment 2

The embodiment provides a method for forming an ultrafine-pitch all-copper interconnect structure, which includes the following steps.
(S1) Ethylene glycol, gelatin and methylcellulose were added to nano-copper powders to adjust a mass percentage concentration of the nano-copper powders to 80%, so as to obtain a nano-copper paste.
(S2) A chip with a copper pillar diameter of 51 μm, a chip pitch of 10 μm, and 200 copper pillar bumps and a substrate were selected. The substrate and the chip were ultrasonically cleaned with dilute sulfuric acid to improve an adhesion of subsequent copper paste dipping.
(S3) The substrate was loaded into a bonding machine, and the chip with copper pillars with I/O ports was sucked and flipped by the bonding machine, thereby allowing the copper pillars to face outward.
(S4) The chip was sucked by a suction nozzle of the bonding machine so that the copper pillars were immersed in the nano-copper paste to dip the nano-copper paste and lifted.
(S5) A nitrogen gas was fed, and the copper pillars were aligned respectively with copper pads on the substrate through an optical system of the bonding machine, bonded with the substrate at 5 MPa and 260° C. under an ultrasonic frequency of 50 kHz.
(S6) After cooling at room temperature, an ultrafine-pitch all-copper semiconductor interconnect structure was obtained. After testing, an overall shear strength was 23.13 MPa, a shear strength of the copper pillars was 0.12 N/bump, a resistivity was 6.2 μΩ·M cm, and a high-temperature storage test pass rate was 98%.

### Embodiment 3

The embodiment provides a method for forming an ultrafine-pitch all-copper interconnect structure, which includes the following steps.
(S1) A nano-copper paste was prepared by a chemical method and adjusted to a mass percentage concentration of 85% by adding chloroform, 2-methylimidazole and tertiary amine.
(S2) A chip having 100 copper pillar bumps with a diameter of 20 μm and a pitch of 40 μm, and a substrate were selected. The substrate and the chip were subjected to Ar plasma treatment to clean an activated surface, with a flow rate of 140 sccm, a RF power of 100 W and pressure of 130 Pa, and then subjected to N₂ plasma treatment to passivate the surface to prevent oxidation with a flow rate of 250 sccm, a RF power of 100 W and pressure of 130 Pa.
(S3) The substrate was loaded into a bonding machine, and the chip with copper pillars with I/O ports was sucked and flipped by the bonding machine, thereby allowing the copper pillars to face outward.
(S4) The chip was sucked by a suction nozzle of the bonding machine so that the copper pillars were immersed in the nano-copper paste to dip the nano-copper paste and lifted.
(S5) A hydrogen-argon mixture gas (95% Ar+5% H₂) was fed, and the copper pillars were aligned respectively with copper pads on the substrate through an optical system of the bonding machine, bonded with the substrate at 2 MPa and 200° C. under an ultrasonic frequency of 10 kHz.
(S6) After cooling at room temperature, an ultrafine-pitch all-copper semiconductor interconnect structure was obtained. After testing, an overall shear strength was 18.38 MPa, a shear strength of the copper pillars was 0.21 N/bump, a resistivity was 14.5 μΩ·M cm, and a high-temperature storage test pass rate was 95%.

### Embodiment 4

The embodiment provides a method for forming an ultrafine-pitch all-copper interconnect structure, which includes the following steps.
(S1) An in-situ nano-copper paste was prepared by a chemical method and adjusted to a mass percentage concentration of 90% by adding acetone, phenylimidazole and acid anhydride.
(S2) A chip having 50 copper pillar bumps with a diameter of 15 μm and a pitch of 30 μm, and a substrate were selected. The substrate and the chip were cleaned with dilute hydrochloric acid and then subjected to H₂ plasma treatment with a flow rate of 300 sccm, a RF power of 100 W and pressure of 100 Pa.
(S3) The substrate was loaded into a bonding machine, and the chip with copper pillars with I/O ports was sucked and flipped by the bonding machine, thereby allowing the copper pillars to face outward.
(S4) The chip was sucked by a suction nozzle of the bonding machine so that the copper pillars were immersed in the nano-copper paste to dip the nano-copper paste and lifted.
(S5) Argon gas was fed, and the copper pillars were aligned respectively with copper pads on the substrate through an optical system of the bonding machine, bonded with the substrate at 10 MPa and 300° C. under an ultrasonic frequency of 20 kHz.
(S6) After cooling at room temperature, an ultrafine-pitch all-copper semiconductor interconnect structure was obtained. After testing, an overall shear strength was 31.59 MPa, a shear strength of the copper pillars was 0.45 N/bump, a resistivity was 4.6 μΩ·cm, and a high-temperature storage test pass rate was 98%.

### Embodiment 5

The embodiment provides a method for forming an ultrafine-pitch all-copper interconnect structure, which includes the following steps.
(S1) Terpineol, gum arabic and ethyl cellulose were added to nano-copper powders to adjust a mass percentage concentration of the nano-copper powders to 90%, so as to obtain a nano-copper paste.
(S2) A chip with a copper pillar diameter of 25 μm, a chip pitch of 50 μm, and 80 copper pillar bumps and a substrate were selected. The substrate and the chip were subjected RCA cleaning, and then the chip was immersed in a propanethiol solution (1 mM).
(S23) The chip was subjected to nitrogen purging in a vacuum dry box and cold argon plasma treatment at room temperature to remove a protective layer, where a flow rate of the cold argon plasma treatment is 300 sccm.
(S3) The substrate was loaded into a bonding machine, and the chip with copper pillars with I/O ports was sucked and flipped by the bonding machine, thereby allowing the copper pillars to face outward.
(S4) The chip was sucked by a suction nozzle of the bonding machine so that the copper pillars were immersed in the nano-copper paste to dip the nano-copper paste and lifted.
(S5) Nitrogen gas was fed, and the copper pillars were aligned respectively with copper pads on the substrate through an optical system of the bonding machine, bonded with the substrate at 50 MPa and 200° C. under an ultrasonic frequency of 80 kHz.
(S6) After cooling at room temperature, an ultrafine-pitch all-copper semiconductor interconnect structure was obtained. After testing, an overall shear strength was 25.43 MPa, a shear strength of the copper pillars was 0.24 N/bump, a resistivity was 12.7 μΩ·cm, and a high-temperature storage test pass rate was 97%.

In summary, the ultrafine-pitch all-copper semiconductor interconnect structures described in Embodiments 2-5 have an overall shear strength of 18.38-31.59 MPa, a shear strength of the copper pillars of 0.12-0.42 N/bump, a resistivity of 4.6-14.5 μΩ·cm, and a high-temperature storage test pass rate of 95%-98%, which means high shear strength, low resistivity, and high pass rate of high-temperature storage test, thereby achieving a limit of ultrafine-pitch interconnection, enabling finer-pitch interconnection, and meeting requirements of high-density packaging.

An ultrafine-pitch all-copper interconnect structure is provided according to an embodiment of the present disclosure. The ultrafine-pitch all-copper is fabricated by the method of Embodiments 1-5 described above. The ultrafine-pitch all-copper can achieve finer pitch interconnection and meet requirements of high-density packaging.

The embodiments disclosed above are merely illustrative of the disclosure, and are not intended to limit the present disclosure. It should be understood that any modifications, changes and replacements made by those skilled in the art without departing from the spirit of the disclosure shall fall within the scope of the disclosure defined by the appended claims.

What is claimed is:

1. A method for forming an ultrafine-pitch all-copper interconnect structure, comprising:
step (1) mixing nano-copper particles with a solvent, a dispersant and a viscosity modifier to prepare a nano-copper paste;
step (2) selecting and cleaning a chip and a substrate followed by pretreatment; wherein the chip has 4-500 copper pillars with input/output (I/O) ports; the copper pillars each have a diameter of 5-50 μm; the chip has a pitch of 10-100 μm; and the pretreatment is acid treatment, plasma treatment, self-assembled monolayer (SAM) or a combination thereof;
step (3) loading the substrate into a bonding machine, sucking, by the bonding machine, the chip and flipping the chip, such that the copper pillars face outward;
step (4) sucking the chip by a suction nozzle of the bonding machine to dip the copper pillars in the nano-copper paste;
step (5) feeding a protective gas, aligning the copper pillars respectively with copper pads on the substrate through an optical system of the bonding machine and performing bonding at a preset pressure and a preset temperature under ultrasonication; and
step (6) performing cooling at room temperature to obtain the ultrafine-pitch all-copper interconnect structure.

2. The method of claim 1, wherein in step (1), the nano-copper particles have a particle size of 100 nm or less; and a mass percentage concentration of the nano-copper particles in the nano-copper paste is 80% or more.

3. The method of claim 2, wherein in step (1), the solvent is selected from the group consisting of ethylene glycol, terpineol, polyethylene glycol, rosin, acetone, chloroform, cyclohexane, epichlorohydrin, epoxy resin, primary amine, tertiary amine, and a combination thereof;
the dispersant is selected from the group consisting of gum arabic, polyvinyl alcohol, polyethylene glycol, gelatin, polyvinyl imidazolidinone, 1-methylimidazole, 2-methylimidazole, 4-methylimidazole, phenylimidazole, 2-ethylimidazole, and a combination thereof; and
the viscosity modifier is selected from the group consisting of methylcellulose, ethylcellulose, hydroxycellulose, primary amine, tertiary amine, acid anhydride and a combination thereof.

4. The method of claim 1, further comprising:
after step (2), subjecting the chip to nitrogen purging in a vacuum dry box and cold argon plasma treatment at room temperature;
wherein a flow rate of the cold argon plasma treatment is 300 sccm.

5. The method of claim 1, wherein in step (4), the suction nozzle of the bonding machine is operated in a closed environment in the presence of the protective gas.

6. The method of claim 1, wherein in step (5), the protective gas is an inert gas or a reducing gas; the inert gas is nitrogen, argon or helium; and the reducing gas is hydrogen, formaldehyde or carbon monoxide.

7. The method of claim 1, wherein in step (5), the bonding is performed at 150-300° C. and 0-50 MPa under an ultrasonic frequency of 0-100 kHz.

8. An ultrafine-pitch all-copper interconnect structure, wherein the ultrafine-pitch all-copper interconnect structure is produced by the method of claim 1.
